(19) United States
(12) Patent Application Publication
(10) Pub. No.: US 2026/0156780 A1
(43) Pub. Date: Jun. 4, 2026

(54) COOLING SYSTEMS FOR COMPUTER SYSTEM COMPONENTS AND METHODS OF OPERATING THE SAME

(71) Applicant: Taiwan Semiconductor Manufacturing Company, Ltd., Hsinchu (TW)

(72) Inventors: Ching WANG, Hsinchu (TW); Bang-Li WU, Hsinchu (TW); Chien-Chang WANG, Hsinchu (TW); Kuo-Chin CHANG, Hsinchu (TW); Kathy Wei YAN, Hsinchu (TW); Jun HE, Hsinchu (TW)

(73) Assignee: Taiwan Semiconductor Manufacturing Company, Ltd., Hsinchu (TW)

(21) Appl. No.: 18/964,245

(22) Filed: Nov. 29, 2024

(51) Int. Cl. H05K 7/20

(52) U.S. Cl. CPC H05K 7/20327; H05K 7/20318; H05K 7/20818

(57) ABSTRACT

A two-phase cooling system includes an enclosure with a first volume, a second volume, and a heat source located in the first volume. The first volume is configured to contain a liquid coolant such that the liquid coolant is in contact with the heat source, and the second volume is configured to contain a vapor of the liquid coolant. The two-phase cooling system includes a condenser located in the second volume that removes heat from the vapor so that the vapor condenses into a liquid that returns to the first volume. A deflector located in the first volume controls a path of vapor generated by the heat source. A method of cooling a heat source includes diverting, with the deflector, a fraction of vapor generated by a first component away from a second component, thus avoiding decrease in liquid coolant density near the second component thereby increasing cooling efficiency.

### BACKGROUND

Cooling systems are used to maintain optimal temperatures in computer systems, especially for components such as central processing units (CPUs) and graphics processing units (GPUs) that generate considerable heat during operation. There are several types of cooling solutions, including air cooling, liquid cooling, and phase-change cooling. Each has its advantages and is suited for different scenarios depending on factors including performance requirements, space constraints, and budget. Liquid cooling systems are increasingly being adopted in high-performance computing environments where conventional air cooling may fall short in dissipating the heat generated by components such as CPUs and GPUs.

One key advantage of liquid cooling lies in its efficiency at transferring heat away from heat sources. In contrast to air, liquid has a higher heat capacity, enabling it to absorb more heat before reaching critical temperatures. Additionally, liquid cooling systems tend to operate more quietly than their air-cooled counterparts, as they rely on pumps rather than fans for heat dissipation. This reduced noise level can be particularly appealing in environments where noise is a concern. Despite advances in liquid cooling systems, challenges remain and there is an ongoing need for improvement in cooling systems for computer components and data systems.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a two-phase cooling system, according to an embodiment.

FIG. 1B is a top view of the two-phase cooling system of FIG. 1A illustrating one configuration of a condenser, according to an embodiment.

FIG. 1C is a top view of the two-phase cooling system of FIG. 1A illustrating a further configuration of a condenser, according to an embodiment.

FIG. 2A is a three-dimensional perspective view of a two-phase cooling system in a first configuration, according to various embodiments.

FIG. 2B is a three-dimensional perspective view of the two-phase cooling system of FIG. 2A in a second configuration, according to various embodiments.

FIG. 3A is a vertical cross-sectional view of a two-phase cooling system, according to various embodiments.

FIG. 3B is a three-dimensional perspective view of a two-phase cooling system, according to various embodiments.

FIG. 4A is a vertical cross-sectional view of a two-phase cooling system in a first configuration, according to various embodiments.

FIG. 4B is a vertical cross-sectional view of the two-phase cooling system of FIG. 4A in a second configuration, according to various embodiments.

FIG. 5A is a side view of a two-phase cooling system that includes a deflector, according to various embodiments.

FIG. 5B is a vertical cross-sectional view of a two-phase cooling system that includes a deflector, according to various embodiments.

FIG. 6A is a three-dimensional cutaway view of a single-suction impeller used in a two-phase cooling system, according to various embodiments.

FIG. 6B is a three-dimensional cutaway view of a double-suction impeller used in a two-phase cooling system, according to various embodiments.

FIG. 6C is a cross-sectional view of a flow pattern generated by a double-suction impeller, according to various embodiments.

FIG. 7A is a side view of a two-phase cooling system that includes a deflector, according to various embodiments.

FIG. 7B is a side view of a two-phase cooling system that includes a deflector, according to various embodiments.

FIG. 8A is a side view of a two-phase cooling system that includes a deflector, according to various embodiments.

FIG. 8B is a vertical cross-sectional view of a two-phase cooling system that includes a deflector, according to various embodiments.

FIG. 9 is a schematic illustration of a two-phase cooling system, according to various embodiments.

FIG. 10 is a flowchart illustrating a method of cooling a heat source, according to various embodiments.

FIG. 11 is a flowchart illustrating a method of cooling a heat source, according to various embodiments.

### DETAILED DESCRIPTION

The following disclosure provides many different embodiments, or examples, for implementing various features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Disclosed embodiments are advantageous because they provide two-phase cooling systems having increased cooling efficiency. In this regard, vapor bubbles generated by a first heat-generating component are diverted away from a second heat-generating component thereby avoiding a decrease in liquid coolant density near the second heat-generating component that would otherwise occur if the vapor bubbles generated by the first heat-generating component were not diverted. The relative increase in liquid coolant density near the second heat-generating component increases cooling efficiency.

Liquid cooling is increasingly being adopted in computer servers, particularly in data centers and high-performance computing (HPC) environments. While air cooling has traditionally been the dominant method for cooling servers due to its simplicity and lower initial costs, liquid cooling offers several advantages that make it appealing for certain server deployments. In data centers, where energy efficiency and cooling capacity are important concerns, liquid cooling offers significant benefits. Liquid cooling systems efficiently remove heat from server components, enabling higher-density deployments without risking overheating. This allows data center operators to maximize their server density within the same footprint, reducing the overall space requirements and potentially lowering operational costs.

Liquid cooling also enables more efficient cooling of high-power components, such as CPUs, GPUs, and memory modules, which are increasingly common in modern server architectures. By keeping these components at optimal operating temperatures, liquid cooling improves performance and reliability, leading to better overall server efficiency. Moreover, liquid cooling contributes to energy savings in data centers by reducing the need for mechanical cooling systems, such as air conditioning units. By leveraging liquid cooling solutions that utilize ambient or recycled water, data centers achieve significant reductions in power consumption and cooling costs. As the demand for higher computing densities, energy efficiency, and performance continues to rise, liquid cooling is likely to become increasingly prevalent in server deployments, especially in specialized HPC and hyperscale data center environments.

Liquid cooling technology includes phase-change cooling and two-phase cooling systems. Phase-change cooling and two-phase cooling share the fundamental principle of utilizing phase transitions to achieve cooling, but they differ in their implementation and operation. Phase-change cooling systems employ a refrigerant that undergoes a phase change from liquid to gas and back again to efficiently transfer heat away from heat-generating components. This process involves a closed-loop system that includes a compressor, condenser, expansion valve, and evaporator. The compressor compresses the refrigerant into a high-pressure gas, which then passes through the condenser to release heat and to condense the refrigerant into a liquid. After passing through an expansion valve, the refrigerant evaporates into a low-pressure gas, absorbing heat from the component that is being cooled. This gas is then cycled back to the compressor to repeat the process.

In contrast, two-phase cooling encompasses a broader category of cooling techniques where both liquid and vapor phases of the coolant coexist simultaneously. In these systems, the coolant partially vaporizes as it absorbs heat from the component, and the resulting mixture of liquid and vapor interacts with a heat exchanger (i.e., a condenser) where the vapor condenses back into liquid, releasing the absorbed heat. This condensed liquid then returns to the component to continue the cooling cycle. Thus, while phase-change cooling is a specific type of cooling system involving phase changes between liquid and gas states, two-phase cooling encompasses a wider range of techniques utilizing both liquid and vapor phases of the coolant concurrently.

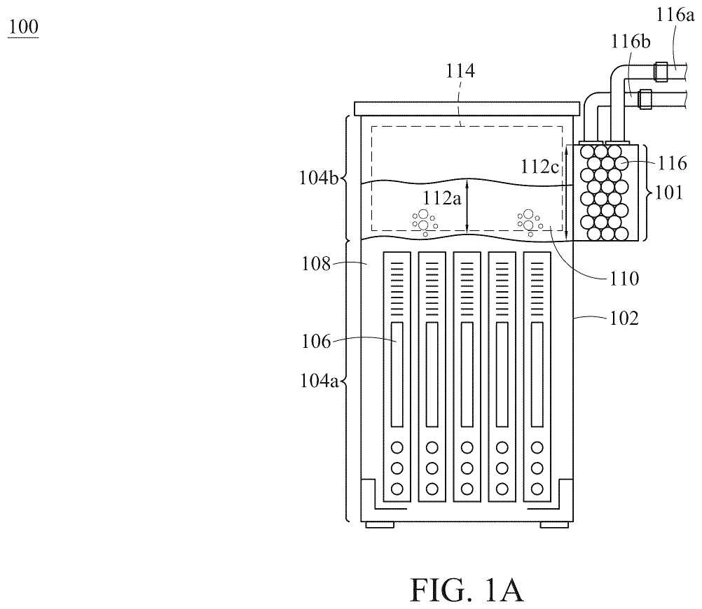

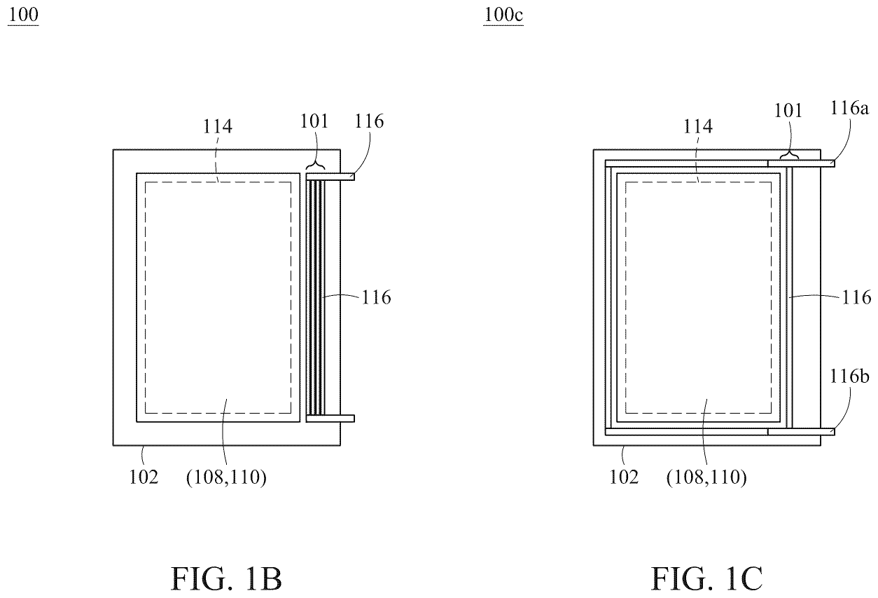

FIG. 1A is a vertical cross-sectional view of a two-phase cooling system 100, according to an embodiment. FIG. 1B is a top view of the two-phase cooling system 100 of FIG. 1A illustrating one configuration of a condenser 101, and FIG. 1C is a top view of a two-phase cooling system 100c that is similar to the cooling two-phase cooling system 100a of FIG. 1A. FIG. 1C illustrates an alternative configuration of a condenser 101, according to another embodiment. As shown in FIG. 1A, the two-phase cooling system 100 includes an enclosure 102 having a first volume 104a and a second volume 104b. The two-phase cooling system 100 includes a heat source 106 located in the first volume 104a and a liquid coolant 108 located in the first volume 104a such that the liquid coolant 108 is in contact with the heat source 106. As described above, the two-phase cooling system 100 may be part of a computing system, computer server, data center, etc. As such, in some embodiments, a computing device that generates heat functions as the heat source 106.

As the system is operated, heat generated by the heat source 106 is absorbed by the liquid coolant 108, which generates a vapor 110. As shown in FIG. 1A, the vapor 110 partially fills the second volume 104b. If the system were in thermodynamic equilibrium, one might expect that the vapor 110 would uniformly fill the second volume 104b. However, during operation, the two-phase cooling system 100 is not in thermodynamic equilibrium, but rather, is in a non-equilibrium steady state in which the vapor 110 is continually generated by heat absorbed by the liquid coolant 108 from the heat source 106. In turn, the vapor 110 generated by the liquid coolant 108 is continually condensed back into condensed liquid coolant by the condenser 101, and the liquid coolant returns to the first volume 104a. In this way, heat is transferred from the heat source 106 to the liquid coolant 108, to the vapor 110, to the condenser 101, and finally out of the system.

Due to the non-equilibrium operation of the two-phase cooling system 100, the vapor 110 does not uniformly fill the second volume 104b. Rather, the vapor 110 has a density distribution characterized by a first height 112a. For example, the vapor 110 has a density distribution that decreases with distance above a surface of the liquid coolant 108 with a characteristic length scale corresponding to the first height 112a. In this regard, in some embodiments, the vapor density distribution is characterized by an exponentially decreasing function of distance above the surface of the liquid coolant 108, with the first height 112a identified as a characteristic length scale of the exponential density dependence. In general, the second volume 104b includes a mixture of vapor 110 and air. The vapor 110 will tend to reside in the bottom portion of the second volume 104b because it has a greater density (e.g., 0.012 g/ml in some embodiments) than that of air (i.e., 0.0013 g/ml).

As shown in FIGS. 1A and 1B, the condenser 101 is located adjacent to a central region 114 of the second volume 104b such that the vapor 110 comes in contact with the condenser 101. The condenser includes a conduit 116 through which a condenser coolant (not shown) flows, such that the condenser coolant absorbs heat from a portion of the vapor 110 that comes in contact with the conduit 116. As shown in FIG. 1A, the conduit 116 includes an inlet conduit 116a and an outlet conduit 116b that allows condenser coolant to flow into and out from the condenser 101. Various materials can be used for the condenser coolant, such as water, a refrigerant, etc.

The degree to which the vapor 110 interacts with the condenser 101 depends on the first height 112a of the vapor. As described above, the first height 112a depends on the non-equilibrium state of the vapor 110. As such, the first height 112a is a function of a rate at which heat is generated by the heat source 106 and a rate at which heat is removed from the vapor 110 by the condenser 101. The heat generation and removal rates further depend on the temperature difference between the heat source 106 and the condenser 101 as well as on the cooling efficiency between the condenser 101 and the vapor 110. As shown in FIG. 1A, the vapor 110 does not fully overlap with the condenser 101 because the vapor 110 does not fill the second volume 104b.

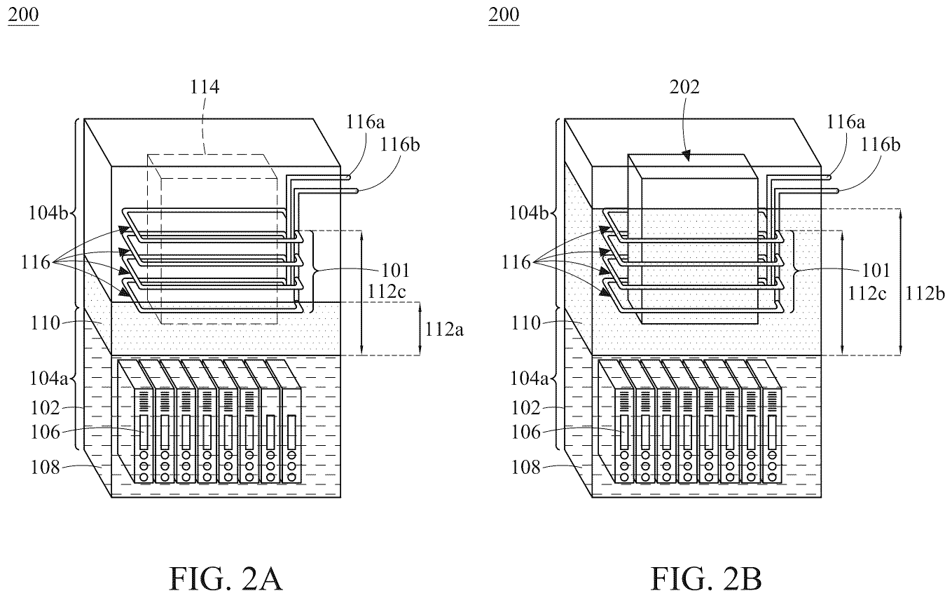

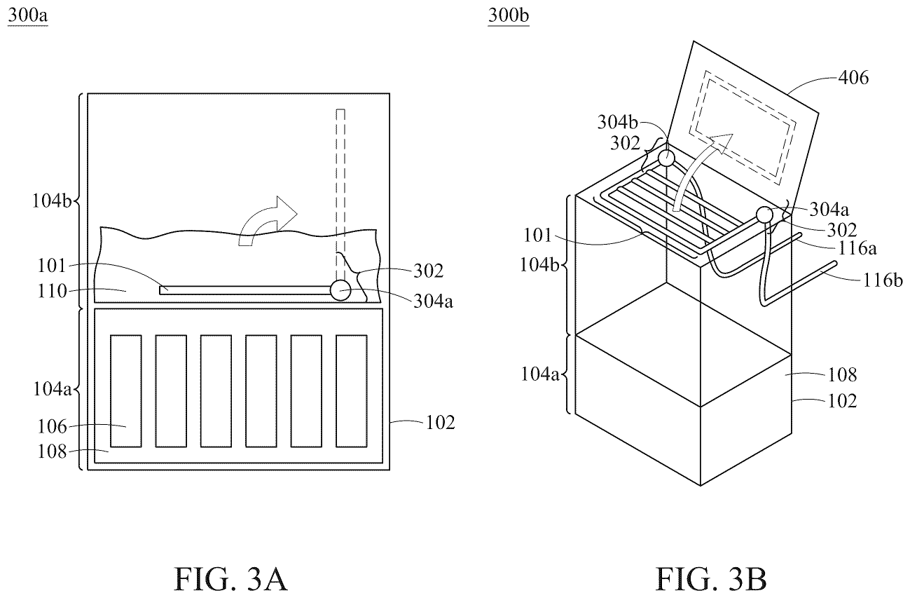

According to some embodiments, described below with reference to FIGS. 3A and 3B, a position of the condenser 101 is controlled by a positioning device 302, which is attached to attached to the condenser 101, which controls the position or orientation of the condenser 101 within the second volume 104b. As such, the position or orientation of the condenser 101 is adjusted to optimize a spatial overlap between the condenser 101 and the vapor 110. In this regard, the cooling efficiency between the vapor 110 and the condenser 101 is increased. Alternatively, in other embodiments as described with reference to FIG. 2B, a vapor control device (i.e., a space-filing device 202) is used to increase a height of the vapor 110 to a second height 112b, which is greater than the first height 112a, thus increasing the cooling efficiency between the vapor 110 and the condenser 101.

In some embodiments, the condenser conduit 116 is formed as a coil (e.g., see FIGS. 1B and 1C) extending vertically to a third height 112c above a surface of the liquid coolant 108 (e.g., see FIGS. 1A, 2A, and 2B). As shown in FIGS. 1B and 1C, the condenser 101 is configured to leave the central region 114 of the second volume 104b free of any components of the condenser 101. Leaving such a central region 114 free is advantageous by providing a space that may be accessed during installation and maintenance of the computer system components that are housed in the first volume 104a. For example, as shown in FIG. 1B, the condenser 101 is located in a space that is adjacent to the central region 114.

Alternatively, as shown in FIG. 1C, the condenser 101 is formed as a coil around a perimeter of the central region 114, in various embodiments. Although the central region 114 provides a convenient access volume for maintenance operations, its presence represents a disadvantage in terms of cooling efficiency between the condenser 101 and the vapor 110. In this regard, the central region 114 represents a volume in which there is no spatial overlap between the vapor 110 and the condenser 101, and as such, there is no coupling between the condenser 101 and the vapor 110 in the central region 114. However, the central region 114 provides a space to accommodate a vapor control device taking the form of a space-filling device 202, which is used to displace the vapor 110 toward the condenser 101, as described in greater detail below (e.g., see FIGS. 2A and 2B). Alternatively, in other embodiments, the condenser is configured to have a geometry that spans the central region 114 but is reconfigurable to be movable so that, during maintenance operations, the condenser 101 is repositioned or removed, as needed, to leave a space within the central region 114, as described with reference to FIGS. 3A and 3B, below.

FIG. 2A is a three-dimensional perspective view of a two-phase cooling system 200 in a first configuration, and FIG. 2B is a three-dimensional perspective view of the two-phase cooling system 200 of FIG. 2A in a second configuration, according to various embodiments. As shown in FIGS. 2A and 2B, the two-phase cooling system 200 includes an enclosure 102 having a first volume 104a and a second volume 104b, a heat source 106 located in the first volume 104a, and a liquid coolant 108 located in the first volume 104a such that the liquid coolant 108 is in contact with the heat source 106. A vapor 110 that partially fills the second volume 104b is generated by the liquid coolant 108 when heat generated by the heat source 106 is absorbed by the liquid coolant 108. As shown in FIGS. 2A and 2B, a condenser 101 is located in the second volume 104b and is configured to remove heat from the vapor 110. By removing heat from the vapor 110, the condenser 101 causes the vapor 110 to condense into condensed liquid coolant that returns to the first volume 104a.

In contrast to the two-phase cooling system 100 of FIGS. 1A to 1C, the two-phase cooling system 200 further includes a space-filling device 202 located in the second volume 104b, as shown in FIG. 2B. The space-filling device 202 partially fills the second volume 104b and thereby displaces the vapor 110 from a portion of the second volume 104b. The displaced vapor 110 fills areas surrounding the space-filling device 202 and, as such, the height of the vapor 110 is increased from the first height 112a, which characterizes the vapor 110 when the space-filling device 202 is removed from the second volume 104b to the second height 112b, which characterizes the vapor 110 when the space-filling device 202 is placed within the second volume 104b. Alternatively, the space-filling device 202 may be removed from the two-phase cooling system 200, thereby leaving the central region 114 free, during installation and maintenance operations. Various space-filling devices 202 are used in corresponding embodiments.

As shown in FIGS. 1A, 2A, and 2B, the condenser 101 spatially extends in a vertical direction characterized by a third height 112c. In this regard, the conduit 116 is formed as a coil extending vertically to a third height 112c above a surface of the liquid coolant 108. As further shown in FIGS. 1A, 2A, and 2B, the third height 112c is greater than the first height 112a such that when the space-filling device 202 is placed within the second volume 104b the vapor 110 is displaced, thereby increasing a degree to which the vapor 110 comes in contact with the condenser 101. As such, the presence of the space-filling device 202 increases the cooling efficiency between the vapor 110 and the condenser 101. Alternatively, in other embodiments, the condenser 101 has other configurations and has a position or orientation that is adjustable to increase overlap between the condenser 101 and the vapor 110, as described in greater detail with reference to FIGS. 3A and 3B, below.

The first height 112a of the vapor 110 above the surface of the liquid coolant is a function of the temperature of the liquid coolant 108, the temperature of the condenser 101, and the specific properties of the liquid coolant 108. In certain embodiments, the liquid coolant 108 is a fluorine-based chemical having a boiling point between 46° C. and 55° C., a latent heat between 90 KJ/kg and 125 KJ/kg, and a vapor pressure between 30 kPa and 40 kPa at a temperature of approximately 20° C. Some example chemicals that may be used as the liquid coolant 108 are listed as follows: HT-55 ((perfluoropolyether) (1-propene, 1,1,2,3,3,3-hexafluoro-, oxidized, polymerized)) available from Galden; Novec 7200 (ethyl nonafluoroisobutyl ether) available from 3M; FC16P (1,1,1,2,2,4,5,5,5-nonafluoro-4-(trifluoromethyl)-3-pentanone) available from Taimax; Novec 649 (1,1,1,2,2,4,5,5,5-nonafluoro-4-(trifluoromethyl)-3-pentanone) available from 3M; FC-3284 (perfluoro compounds, C5-18) available from 3M; FC18P (2-pentene, 1,1,1,2,3,4,5,5,5-nonafluoro-4-(trifluoromethyl)) available from Taimax; IM6 (perfluoro (4-methylpent-2-ene)) available from Inventec; 2100A (perfluoro (4-methylpent-2-ene)) available from Noah; DAISAVE SS-54 (1,1,2,3,3,3-hexafluoropropyl methyl ether) available from Daikin; and Opteon 2P50 (hydrofluoroolefin) available from Chemours.

FIG. 3A is a vertical cross-sectional view of a two-phase cooling system 300a, and FIG. 3B is a vertical cross-sectional view of a two-phase cooling system 300b, according to various embodiments. As shown in FIGS. 3A and 3B, the two-phase cooling system 300 includes an enclosure 102 having a first volume 104a and a second volume 104b, a heat source 106 located in the first volume 104a, and a liquid coolant 108 located in the first volume 104a such that the liquid coolant 108 is in contact with the heat source 106. A vapor 110 that partially fills the second volume 104b is generated by the liquid coolant 108 when heat generated by the heat source 106 is absorbed by the liquid coolant 108. As shown in FIGS. 3A and 3B, a condenser 101 is located in the second volume 104b and is configured to remove heat from the vapor 110.

By removing heat from the vapor 110, the condenser 101 causes the vapor 110 to condense into condensed liquid coolant that returns to the first volume 104a. In contrast to the two-phase cooling system 100 of FIGS. 1A to 1C, and the two-phase cooling system 200 of FIGS. 2A and 2B, the two-phase cooling system 300 of FIGS. 3A and 3B further includes a positioning device 302, located in the second volume 104b, which is attached to the condenser 101 and controls a position or orientation of the condenser 101 within the second volume 104b. As shown in FIGS. 3A and 3B, the condenser 101 is configured to have a planar geometry that spans an area of the central region 114 of the second volume 104b.

According to various embodiments, the positioning device 302 is provided with a hinge (304a, 304b) that is configured to allow the condenser 101 to be positioned in a first angular configuration (e.g., positioned horizontally) and a second angular configuration (e.g., positioned vertically; see dashed lines in FIG. 3A). In further embodiments, the positioning device 302 is configured to allow the condenser 101 to be positioned at any angle within a predetermined range of angles (e.g., between 0 and 90 degrees relative to the horizontal direction, etc.). In various embodiments, the positioning device 302 also provides a fluid connection to the condenser 101.

For example, according to various embodiments, the hinge (304a, 304b) includes a first portion 304a, which provides a fluid connection between the condenser 101 and an inlet conduit 116a, and a second portion 304b, which provides a fluid connection between the condenser 101 and an outlet conduit 116b, as shown in FIG. 3B. According to various embodiments, at least one of the first portion 304a or the second portion 304b is provided as a linear hinge, a two-dimensional hinge, or a three-dimensional ball hinge, in respective embodiments. For example, as shown in FIGS. 3A and 3B, the hinge (304a, 304b) is configured to allow rotational motion around an axis (e.g., an axis coinciding with the inlet conduit 116a and the outlet conduit 116b).

In other embodiments, the positioning device 302 does not need to provide a fluid connection. For example, in some embodiments (not shown) a three-dimensional ball hinge is attached to the condenser 101 such that the condenser 101 has three-dimensional positional freedom relative to a contact point of the three-dimensional ball hinge. In such embodiments, the inlet conduit 116a and the outlet conduit 116b are connected to flexible tubing (not shown) that allows condenser fluid to be provided to the condenser 101 without further constraining a three-dimensional positioning of the condenser 101.

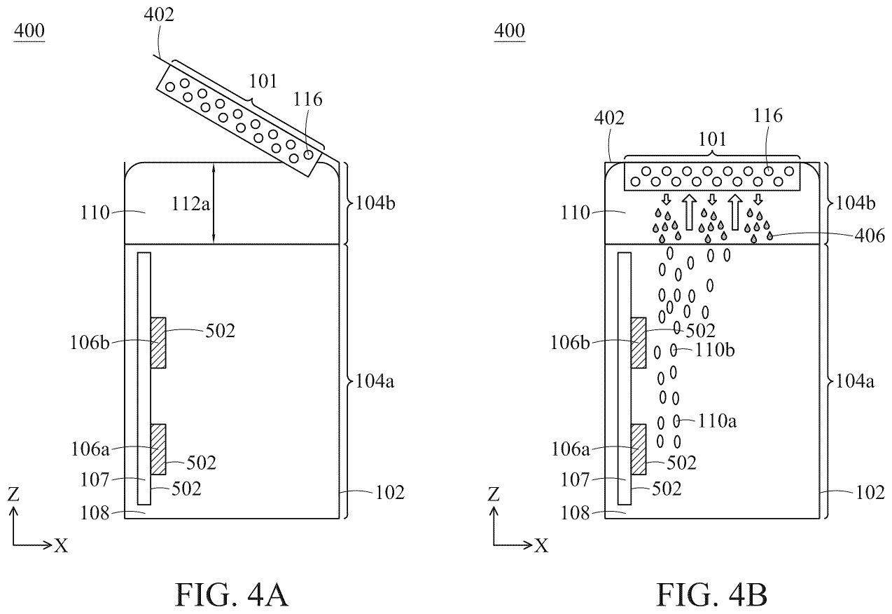

FIG. 4A is a vertical cross-sectional view of a two-phase cooling system 400 in a first configuration, and FIG. 4B is a vertical cross-sectional view of the two-phase cooling system 400 of FIG. 4A in a second configuration, according to various embodiments. As shown in FIGS. 4A and 4B, the two-phase cooling system 400 includes an enclosure 102 having a first volume 104a and a second volume 104b, a heat source (106a, 106b) located in the first volume 104a, and a liquid coolant 108 located in the first volume 104a such that the liquid coolant 108 is in contact with the heat source (106a, 106b).

In contrast to the embodiments of FIGS. 1A to 3B, in the embodiments of FIGS. 4A and 4B, the condenser 101 is mounted to a cover 402 of the two-phase cooling system 400, and a size of the second volume 104b is chosen to be sufficiently small such that a vapor 110 formed over a surface of the liquid coolant 108 essentially fills the second volume 104b. Thus, when the cover 402 is closed, as shown in FIG. 4B, a top portion of the vapor 110 comes in contact with the condenser 101. Thus, according to the embodiment of FIGS. 4A and 4B, a first height 112a that characterizes a vertical spatial extent of the vapor 110 is comparable to the height of the second volume 104b.

In the two-phase cooling system 400 of FIGS. 4A and 4B, the heat source (106a, 106b) is a computing device that is located in the first volume 104a such that the liquid coolant 108 comes in contact with the heat source (106a, 106b). As shown, the computing device includes a first heat-generating component 106a, and a second heat-generating component 106b located above the first heat-generating component 106a. The first heat-generating component 106a and a second heat-generating component 106b each have a vertical surface 502 that comes in contact with the liquid coolant 108 such that the liquid coolant 108 absorbs heat from the vertical surface 502 of each of the first heat-generating component 106a and a second heat-generating component 106b.

According to various embodiments, the first heat-generating component 106a is a first circuit component and the second heat-generating component 106b is a second circuit component. Each of the first heat-generating component 106a and the second heat-generating component 106b is mounted to a substrate 107 such as a printed circuit board (PCB). Each of the first and second circuit components (106a, 106b) generates heat but the first heat-generating component 106a need not be the same type of circuit component as the second heat-generating component 106b. In this regard, first and second circuit components (106a, 106b) may include various types of circuit components including CPUs, GPUs, memory units, power control circuits, etc., in respective embodiments. In this regard, in some embodiments, the first heat-generating component 106a and a second heat-generating component 106b are each the same type of circuit component, and in other embodiments, the first heat-generating component 106a and a second heat-generating component 106b are different from one another.

As shown in FIG. 4B, during operation of the two-phase cooling system 400, the heat source (106a, 106b) generates sufficient heat to cause boiling of the liquid coolant 108. As such, the vapor 110 formed in the second volume 104b starts as a plurality of vapor bubbles (110a, 110b) generated within the liquid coolant 108 that flow through the liquid coolant 108 toward a surface of the liquid coolant 108 (i.e., shown as an interface between the liquid coolant 108 in first volume 104a and the vapor 110 in second volume 104b). As shown in FIG. 4B, each of the first and second circuit components (106a, 106b) acts as a source of vapor bubbles (106a, 106b). In this regard, the first heat-generating component 106a generates first vapor bubbles 110a and the second heat-generating component 106b generates second vapor bubbles 110b. As in other embodiments, described above, the vapor 110 interacts with the condenser 101 such that heat from the vapor 110 is absorbed by the 110. As such, the vapor 110 is cooled and condenses back into condensed liquid coolant 406, which turns to the first volume 104a.

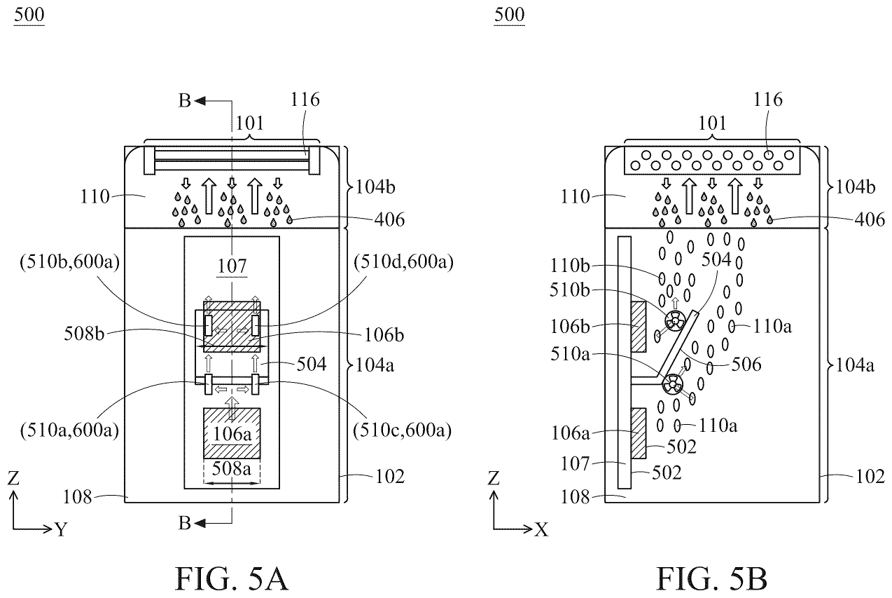

The presence of the vapor bubbles (110a, 110b) causes a reduction in the density of the liquid coolant 108 in regions where the vapor bubbles (110a, 110b) are located. As such, the presence of the first vapor bubbles 110a flowing past the second heat-generating component 106b reduces the density of liquid coolant 108 in the vicinity of the second heat-generating component 106b. As such, the cooling efficiency of the second heat-generating component 106b is reduced due to the presence of the first vapor bubbles 110a generated by the first heat-generating component 106a. To improve cooling efficiency, various embodiments include a deflector 504 that controls a path of the vapor bubbles (110a, 110b) to cause the flow of first vapor bubbles 110a to flow away from the second heat-generating component 106b, as described in greater detail with reference to FIGS. 5A to 9, below.

FIG. 5A is a side view of a two-phase cooling system 500 that includes a deflector 504, and FIG. 5B is a vertical cross-sectional view of the two-phase cooling system 500 of FIG. 5A, according to various embodiments. The vertical cross-sectional view of FIG. 5B is defined by a vertical plane that includes the direction (i.e., the x-direction) that is perpendicular to vertical surface 502 of the heat source (106a, 106b). FIG. 5A is a side view looking along the direction (i.e., the x-direction) that is perpendicular to vertical surface 502 of the heat source (106a, 106b).

As shown in FIGS. 5A and 5B, the deflector 504 is configured to control a path of vapor bubbles (110a, 110b) such that the first vapor bubbles 110a flow away from the first heat-generating component 106a. As such, the second heat-generating component 106b is shielded from the first vapor bubbles 110a that are generated by the first heat-generating component 106a. In this regard, the only vapor bubbles that are proximate to the second heat-generating component 106b are second vapor bubbles 110b that are generated by the second heat-generating component 106b. The deflector 504 thereby prevents the reduction in density of the liquid coolant 108 (due to the first vapor bubbles 110a) near the surface of the second heat-generating component 106b that would otherwise occur in the absence of the deflector 504. As such, the presence of the deflector 504 leads to an increase in the overall cooling efficiency of the two-phase cooling system 500.

As shown in FIG. 5B, the first heat-generating component 106a and the second heat-generating component 106b each have a vertical surface 502 that generates respective first vapor bubbles 110a and second vapor bubbles 110b, respectively. As also shown, the deflector 504 is located between the first heat-generating component 106a and the second heat-generating component 106b. The deflector 504 includes an upwardly angled surface 506 that is neither parallel nor perpendicular to the vertical surface 502 of the heat source. In this way, the deflector 504 is configured to cause the first vapor bubbles 110a generated by the first heat-generating component 106a to flow along a direction parallel to the upwardly angled surface 506 of the deflector 504. As such, the deflector 504 effectively prevents the first vapor bubbles 110a from flowing in a volume occupied by the second vapor bubbles 110b generated by the second heat-generating component 106b.

As shown in FIG. 5A, each of the first heat-generating component 106a and the second heat-generating component 106b has a first width 508a in a horizontal direction (i.e., along the y-direction) and the deflector 504 has a second width 508b that is greater than the first width 508a. Thus, as shown in FIG. 5A, in a side view along a direction perpendicular to the vertical surface of the heat source (i.e., along the x-direction), a projected second area of the deflector 504 overlaps a portion of a first area of the second heat-generating component 106b.

As shown in FIGS. 5A and 5B, the two-phase cooling system 500 includes a first impeller 510a located below the deflector 504 and a second impeller 510b located above the deflector 504. In certain embodiments, the impellers (510a, 510b) are mounted to the deflector 504 and in other embodiments, one or more of the impellers (510a, 510b) are mounted to other structures (not shown) of the two-phase cooling system 500. According to various embodiments, the first impeller 510a is configured to draw the liquid coolant 108 and the first vapor bubbles 110a along the horizontal direction of the deflector 504 toward or away from a central portion of the deflector 504 (e.g., see horizontal arrows) and to eject the liquid coolant 108 and the first vapor 110a upwardly along the lower surface 506 of the deflector 504 (e.g., see vertical arrows).

Similarly, the second impeller 510b is configured to draw the liquid coolant 108 and the second vapor bubbles 110b along the horizontal direction (e.g., see horizontal arrows) of the second heat-generating component 106b toward or away from a center of the second heat-generating component 106b and to eject the liquid coolant and the second vapor upwardly (e.g., see vertical arrows). According to various embodiments, the impellers (510a, 510b) increase a flow rate of liquid coolant 108 moving past the heat-generating components (106a, 106b), which increases a rate at which heat is removed from the heat-generating components (106a, 106b), thereby increasing the cooling efficiency of the two-phase cooling system 500.

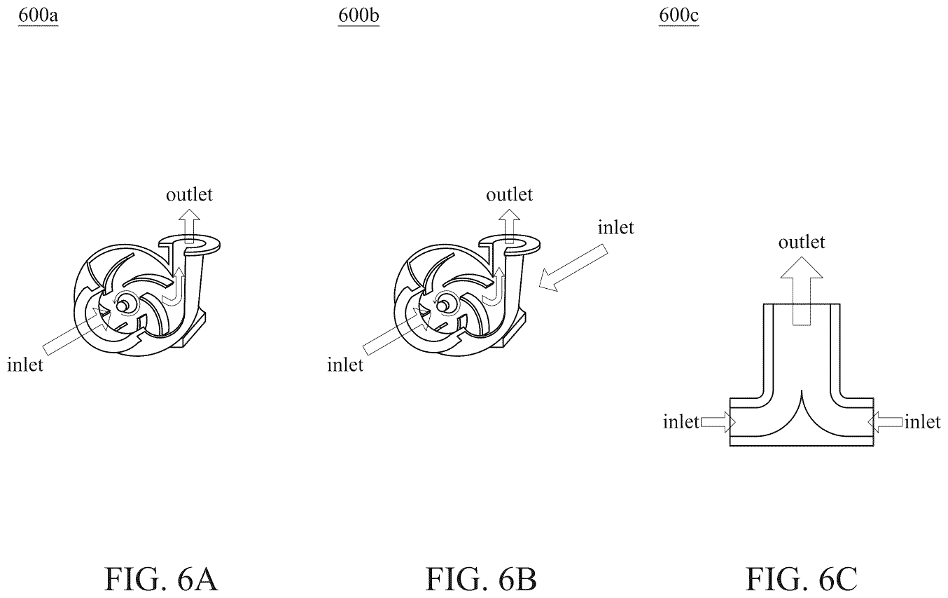

FIG. 6A is a three-dimensional cutaway view of a single-suction impeller 600a, and FIG. 6B is a three-dimensional cutaway view of a double-suction impeller 600b, according to various embodiments. FIG. 6C is a cross-sectional view of a flow pattern 600c generated by a double-suction impeller, according to various embodiments. According to certain embodiments, each of the first impeller 510a and the second impeller 510b of FIGS. 5A and 5B are single-suction impellers as shown in FIG. 6A. Alternatively, in other embodiments, each of the first impeller 510a and the second impeller 510b of FIGS. 5A and 5B are double-suction impellers as shown in FIG. 6B. In still further embodiments, the first impeller 510a and the second impeller 510b need not be the same type of impeller.

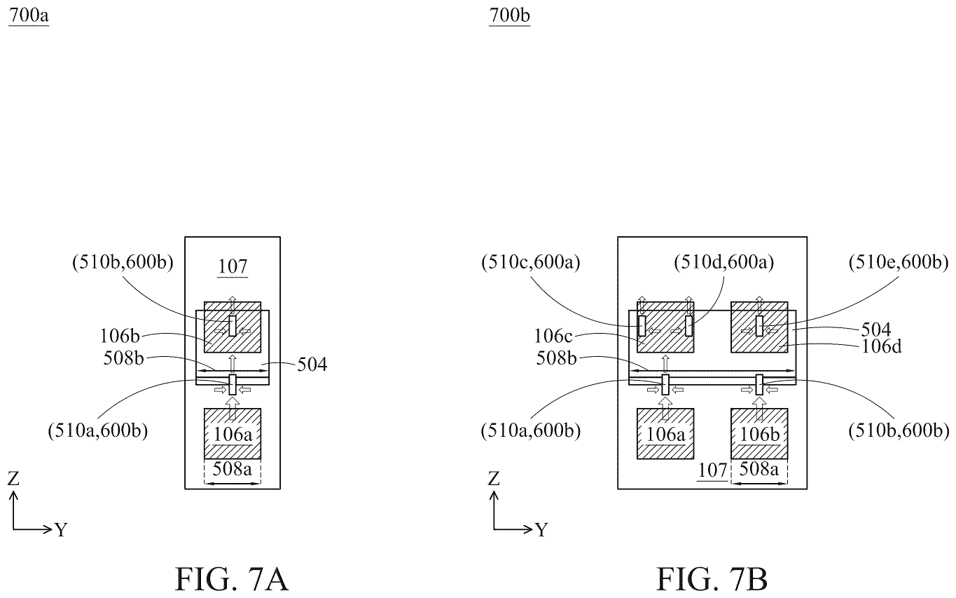

FIG. 7A is a side view of a two-phase cooling system 700a that includes a deflector 504, according to various embodiments. The first two-phase cooling system 700a is similar to the two-phase cooling system 500. In this regard, the first two-phase cooling system 700a includes a first heat-generating component 106a and a second heat-generating component 106b. However, the first two-phase cooling system 700a and the two-phase cooling system 500 differ in terms of the number and configurations of the impellers (510a, 510b). For example, as shown in FIG. 7A, the first two-phase cooling system 700a includes a first impeller 510a that is configured as a double-suction impeller 610b and a second impeller 510b that is configured as a double-suction impeller 610b. In contrast, the two-phase cooling system 500 includes four impellers (510a, 510b, 510c, 510d) that are each configured as single-suction impellers 600a.

FIG. 7B is a side view of a second two-phase cooling system 700b that includes a deflector 504, according to various embodiments. The second two-phase cooling system 700b includes a lower heat-generating component (106a, 106b) and an upper heat-generating component (106c, 106d). As shown, the lower heat-generating component (106a, 106b) includes a first circuit component 106a, and a second circuit component 106b. Similarly, the upper heat-generating component (106c, 106d) includes a third circuit component 106c, and a fourth circuit component 106d. Further, the second two-phase cooling system 700b includes a first impeller 510a configured as a double-suction impeller 600b, a second impeller 510b configured as a double-suction impeller 600b, a third impeller 510c configured as a single-suction impeller 600a, a fourth impeller 510d configured as a single-suction impeller 600a, and a fifth impeller 510e configured as a double-suction impeller 600b.

As shown in FIG. 7B, the deflector 504 has a width 508b that is sufficiently greater than twice the width 508a of the third circuit component 106c and the fourth circuit component 106d such that a projected second area of the deflector 504 overlaps a portion of a first area of the third circuit component 106c and a second area of the fourth circuit component 106d. Thus, the deflector 504 is configured to deflect a flow of vapor bubbles (not shown in FIG. 7B) generated by the lower heat-generating component (106a, 106b) away from the third circuit component 106c and the fourth circuit component 106d. As such, the deflector 504 leads to an increased density of liquid coolant 108 near the third circuit component 106c and the fourth circuit component 106d thereby increasing the cooling efficiency of the second two-phase cooling system 700b relative to comparative embodiments (e.g., see FIGS. 4A and 4B) that do not include the deflector 504.

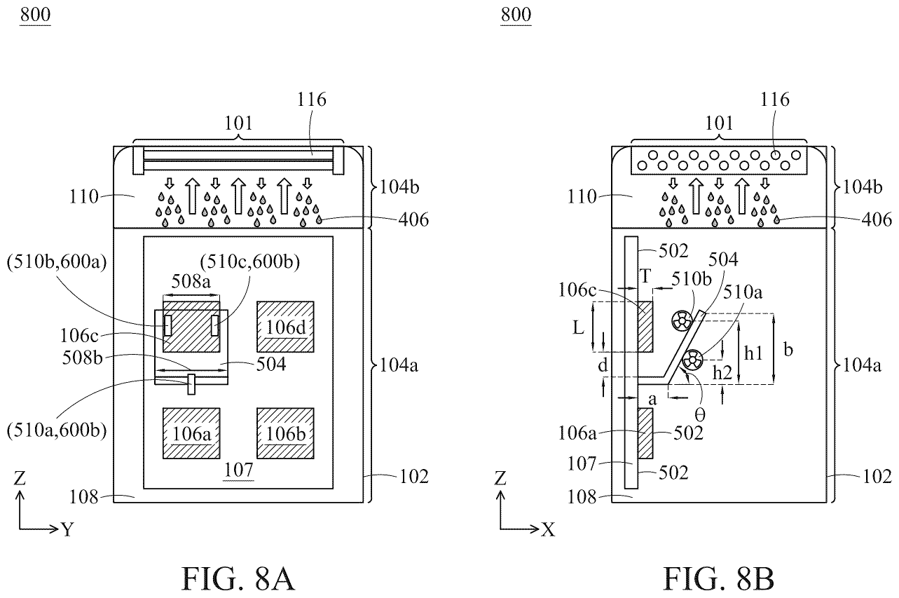

FIG. 8A is a side view of a two-phase cooling system 800 that includes a deflector 504, and FIG. 8B is a vertical cross-sectional view of the two-phase cooling system 800 of FIG. 8A, according to various embodiments. As shown in FIG. 8A, the deflector 504 need not cover all of the upper heat-generating components (106c, 106d). For example, although the two-phase cooling system 800 includes four circuit components (106a, 106b, 106c, 106d), the deflector 504 is configured to only modify the flow of vapor bubbles (not shown) generated by the first circuit component 106a that is located below the third circuit component 106c. Such a configuration is advantageous in embodiments in which the first heat-generating component 106a generates considerably more heat than the second heat-generating component 106b. For example, in such embodiments, the first circuit component 106a generates sufficient heat to cause boiling of the liquid coolant 108, while the second circuit component 106b does not. As such, the second circuit component 106b does not generate vapor bubbles that would otherwise decrease a density of the liquid coolant 108 in the vicinity of the fourth circuit component 106d.

Further, although the above-described embodiments include only one or two circuit components (106a, 106b) for the lower heat-generating component and only one or two circuit components (106c, 106d) for the upper heat-generating component, other embodiments are not so limited. In this regard, other embodiments include a first plurality of m≥1 lower circuit components and a second plurality of n≥1 upper circuit components. Further, in other embodiments, the heat source includes a plurality of vertically stacked rows of the circuit components, where each row need not have the same number of circuit components as other rows. Also, all of the above-described embodiments include only a single PCB having circuit components mounted thereon. Other embodiments need not be so limited. For example, in other embodiments, the various cooling systems (500, 700a, 700b, 800) include a plurality of PCBs (not shown) each having various circuit components stored thereon. In this regard, in various embodiments, the plurality of PCBs are stacked next to one another along a direction perpendicular to the vertical surfaces 502 (i.e., stacked along the x-direction).

FIG. 8B illustrates various geometrical parameters of the two-phase cooling system 800, according to various embodiments. In this regard, according to various embodiments, one or more circuit components are mounted along a horizontal direction to a PCB to form each row. Each PCB includes one or more rows of circuit components, and the system includes one or more PCBs. As shown in FIG. 8B, the deflector 504 includes a horizontal segment having a width “a” that is greater than a thickness “T” of a circuit component. Various other geometric relationships are shown in Table 1, below.

TABLE 1

| | | |
|---|---|---|
| L | length of a circuit | |
| | component | |
| W | width 508b of a circuit | |
| | component | |
| b | extent of deflector 504 in | d + 0.5 L ≤ b ≤ (d + 0.5 L) |
| | the z-direction | |
| c | Width 508a of the | c ≥ 0.5 W |
| | deflector 504 in the y- | |
| | direction | |
| θ | angle of the angled portion | 0 < θ ≤ 90° |
| | of the deflector 504 | |
| d | separation between the | d > 0 |
| | deflector 504 and the | |
| | second circuit component | |
| | 106b | |
| e | number of impellers | e ≥ 1 |
| h1 | height of first impeller | d + 0.5 L ≤ b ≤ (d + L) |
| | 510a above the bottom of | |
| | deflector 504 | |
| h2 | height of second impeller | h2 > 0 |
| | 510b above the bottom of | |
| | deflector 504. | |

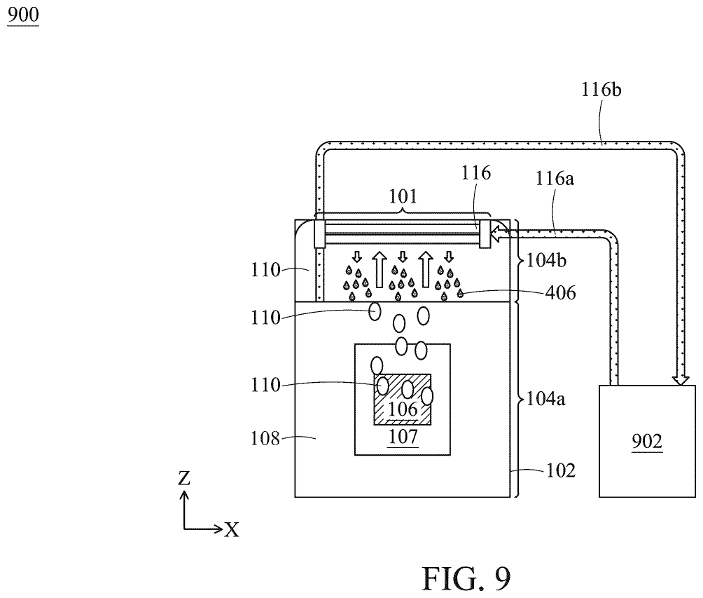

FIG. 9 is a schematic illustration of a two-phase cooling system 900, according to various embodiments. The two-phase cooling system 900 includes many of the components described above with reference to other embodiments. The system 900 further includes a chiller system 902 that provides chilled condenser coolant (not shown) to the condenser 101 through the inlet conduit 116a. The chilled condenser coolant flows through the conduit 116 of the condenser 101 and receives heat from the vapor 110. By extracting heat from the vapor 110, the condenser coolant flowing through the condenser 101 causes the vapor 110 to condense giving rise to condensed liquid coolant 406 that returns to the first volume 104a. The temperature of the condenser coolant is increased due to the absorption of heat by the condenser 101 from the vapor 110. The heated condenser coolant is then returned to the chiller system 902 to be re-cooled and recirculated back to the condenser 101 to continue the cooling process.

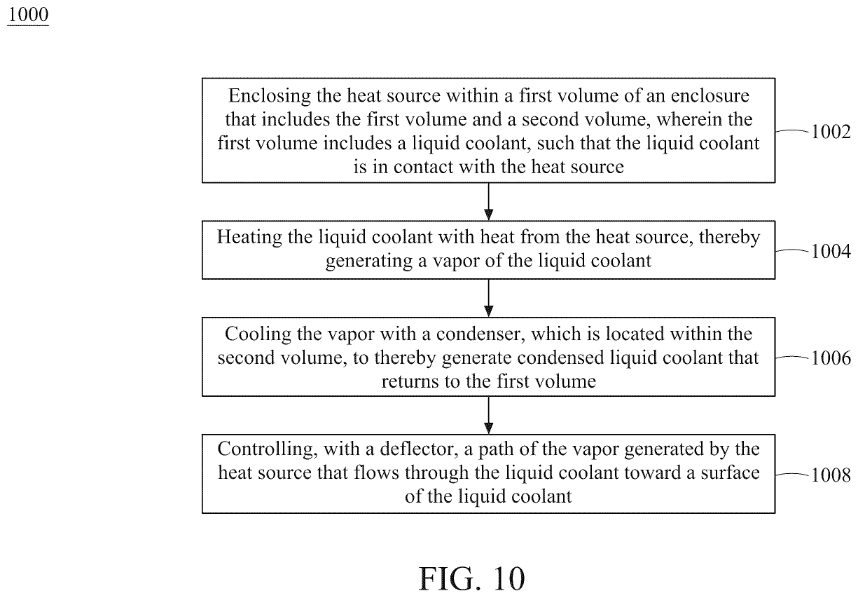

FIG. 10 is a flowchart illustrating a method 1000 of cooling a heat source 106, according to various embodiments. In operation 1002, the method 1000 includes enclosing the heat source 106 within a first volume 104a of an enclosure 102 that includes the first volume 104a and a second volume 104b, wherein the first volume 104a includes a liquid coolant 108, such that the liquid coolant 108 is in contact with the heat source 106. In operation 1004, the method 1000 includes heating the liquid coolant 108 with heat from the heat source 106, thereby generating a vapor 110 of the liquid coolant 108. In operation 1006, the method 1000 includes cooling the vapor 110 with a condenser 101, which is located within the second volume 104b, to thereby generate condensed liquid coolant 406 that returns to the first volume 104a. In operation 1006, the method 1000 includes controlling, with a deflector 504, a path of the vapor 110 generated by the heat source 106 that flows through the liquid coolant 108 toward a surface of the liquid coolant 108.

According to various embodiments, the heat source 106 includes a vertical surface 502 that generates the vapor 110. In this regard, the heat source 106 includes a first heat-generating component 106a located in a lower portion of the heat source, and a second heat-generating component 106b located in an upper portion of the heat source. According to various embodiments, the deflector 504 is located between the first heat-generating component 106a and the second heat-generating component 106b. In various embodiments, the method 1000 further includes causing a first fraction of the vapor 110a generated by the first heat-generating component 106a to be deflected away from the second heat-generating component 106b by the deflector 504.

According to various embodiments, the method 1000 further includes activating a first impeller 510a located below the deflector 504 such that the first impeller 510a draws the liquid coolant 108 and the first fraction of the vapor 110a along a horizontal direction of the deflector 504 toward a central portion of the deflector 504 and to eject the liquid coolant 108 and the first fraction of the vapor 110a upwardly along a lower surface of the deflector 504.

According to various embodiments, the method 1000 further includes activating a second impeller 510b located above the deflector 504 such that the second impeller 510b draws the liquid coolant 108 and a second fraction of the vapor 110b, generated by the second heat-generating component 106b, along the horizontal direction of the second heat-generating component 106b toward or away from a center of the second heat-generating component 106b and ejecting the liquid coolant 108 and the second fraction of the vapor 110b upwardly.

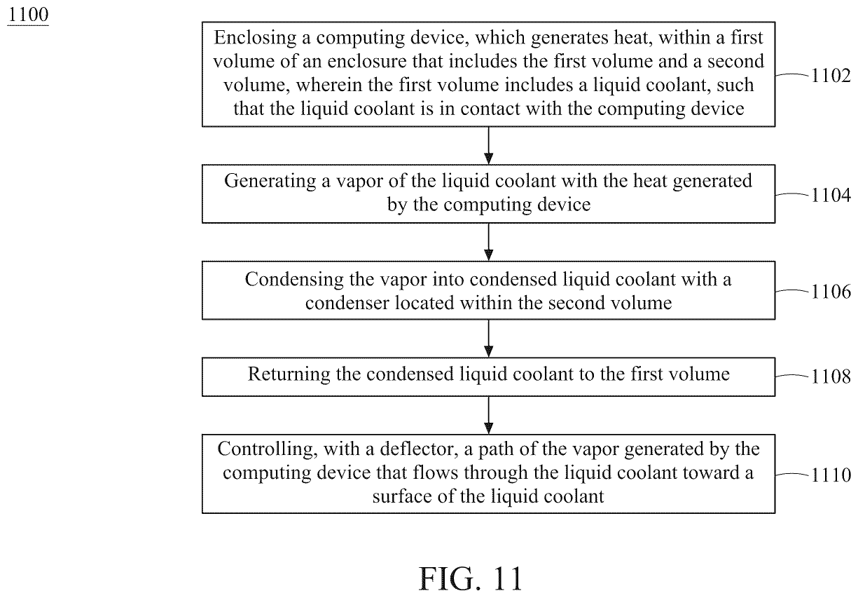

FIG. 11 is a flowchart illustrating a method 1100 of cooling a computing device (106a, 106b), according to various embodiments. In operation 1102, the method 1100 includes enclosing the computing device (106a, 106b), which generates heat, within a first volume 104a of an enclosure 102 that includes the first volume 104a and a second volume 104b, wherein the first volume 104a includes a liquid coolant 108, such that the liquid coolant 108 is in contact with the computing device (106a, 106b). In operation 1104, the method 1100 includes generating a vapor 110 of the liquid coolant 108 with the heat generated by the computing device (106a, 106b). In operation 1106, the method 1100 includes condensing the vapor 110 into condensed liquid coolant 406 with a condenser 101 located within the second volume 104b. In operation 1108, the method 1100 includes returning the condensed liquid coolant 406 to the first volume 104a. In operation 1110, the method 1100 includes controlling, with a deflector 504, a path of the vapor 110 generated by the computing device (106a, 106b) that flows through the liquid coolant 108 toward a surface of the liquid coolant 108.

According to various embodiments, the computing device (106a, 106b) includes a first heat-generating component 106a and a second heat-generating component 106b located above the first heat-generating component 106a and the deflector 504 is located between the first heat-generating component 106a and the second heat-generating component 106b. According to various embodiments, method 1100 further includes causing a first fraction of the vapor 110a generated by the first heat-generating component 106a to be deflected away from the second heat-generating component 106b by the deflector 504.

According to various embodiments, a projected second area of the deflector 504 overlaps a portion of a first area of the second heat-generating component 106b in a side view along a direction perpendicular to a vertical surface 502 of the computing device (106a, 106b). According to various embodiments, the method 1100 further includes activating a first impeller 510a located below the deflector 504 such that the first impeller 510a draws the liquid coolant 108 and the first fraction of the vapor 110a along a horizontal direction of the deflector 504 toward a central portion of the deflector 504 and to eject the liquid coolant 108 and the first fraction of the vapor 110a upwardly along a lower surface of the deflector 504.

According to various embodiments, at least one of the first heat-generating component 106a, or the second heat-generating component 106b includes a plurality of circuit components arranged along a horizontal direction and separated from one another along the horizontal direction. In such embodiments, the method 1100 further includes activating at least one of a first impeller 510a located below the deflector 504 or a second impeller 510b located above the deflector 504 to draw the liquid coolant 108 and the first fraction of the vapor 110a generated by the first heat-generating component 106a or second fraction of the vapor 110b generated by the second heat-generating component 106b respectively away from the first heat-generating component 106a or the second heat-generating component 106b.

Referring to all drawings and according to various embodiments of the present disclosure, a two-phase cooling system (500, 700a, 700b, 800, 900) is provided. The two-phase cooling system (500, 700a, 700b, 800, 900) includes an enclosure 102 including a first volume 104a and a second volume 104b, and a heat source 106 located in the first volume 104a. The first volume 104a is configured to contain a liquid coolant 108 such that the liquid coolant 108 is in contact with the heat source 106, and the second volume 104b is configured to contain a vapor 110 of the liquid coolant 108. The two-phase cooling system (500, 700a, 700b, 800, 900) further includes a condenser 101 located in the second volume 104b that is configured to remove heat from the vapor 110 so that the vapor 110 condenses into a liquid, and a deflector 504 (not shown in two-phase cooling system 900), which is configured to control a path of the vapor 110 generated by the heat source 106 that flows through the liquid coolant 108 toward a surface of the liquid coolant 108.

According to various embodiments, the deflector 504 is configured to cause the vapor 110 to flow away from the heat source 106. According to various embodiments, the heat source 106 includes a vertical surface 502 that generates the vapor 110 and the deflector 504 is configured to cause the vapor 110 to flow away from the vertical surface 502 as the vapor 110 flows upwardly toward the surface of the liquid coolant 108. According to various embodiments, the heat source 106 includes a first heat-generating component 106a located in a lower portion of the heat source and a second heat-generating component 106b located in an upper portion of the heat source. The deflector 504 is located between the first heat-generating component 106a and the second heat-generating component 106b, and the deflector 504 is configured to cause a first fraction of the vapor 110a generated by the first heat-generating component 106a to be deflected away from the second heat-generating component 106b.

According to various embodiments, the deflector 504 is configured to prevent the first fraction of the vapor 110a from flowing in a volume occupied by a second fraction of the vapor 110b generated by the second heat-generating component 106b, and the deflector 504 includes an upwardly angled surface 506 that is neither parallel to nor perpendicular to the vertical surface 502 of the heat source 106. According to various embodiments, the deflector 504 is configured to cause the first fraction of the vapor 110a generated by the first heat-generating component 106a to flow along a direction parallel to the upwardly angled surface 506 of the deflector 504. According to various embodiments, each of the first heat-generating component 106a and the second heat-generating component 106b has a first width 508a in a horizontal direction and the deflector 504 has a second width 508b that is greater than the first width 508a. According to various embodiments, a projected second area of the deflector 504 overlaps a portion of a first area of the second heat-generating component 106b in a side view along a direction perpendicular to the vertical surface 502 of the heat source 106.

According to various embodiments, the two-phase cooling system (500, 700a, 700b, 800, 900) includes a first impeller 510a (not shown in two-phase cooling system 900) located below the deflector 504, such that the first impeller 510a is configured to draw the liquid coolant 108 and the first fraction of the vapor 110a along the horizontal direction of the deflector 504 toward a central portion of the deflector 504 and to eject the liquid coolant 108 and the first fraction of the vapor 110a upwardly along a lower surface of the deflector 504. According to various embodiments, the first impeller 510a is a double-suction impeller that draws the liquid coolant 108 and the first fraction of the vapor 110a from two horizontal directions.

According to various embodiments, the two-phase cooling system (500, 700a, 700b, 800, 900) includes a second impeller 510b located above the deflector 504, such that the second impeller 510b is configured to draw the liquid coolant 108 and the second fraction of the vapor 110b along the horizontal direction of the second heat-generating component 106b toward or away from a center of the second heat-generating component 106b and to eject the liquid coolant 108 and the second fraction of the vapor 110b upwardly.

Disclosed embodiments are advantageous because they provide two-phase cooling systems (500, 700a, 700b, 800, 900) having increased cooling efficiency. In this regard, vapor bubbles 110a generated by a first heat-generating component 106a are diverted away from a second heat-generating component 106b thereby avoiding a decrease in liquid coolant 108 density near the second heat-generating component 106b that would otherwise occur if the vapor bubbles 110a generated by the first heat-generating component 106a were not diverted. The relative increase in liquid coolant 108 density near the second heat-generating component 106b leads to an increase in cooling efficiency.

According to various embodiments, a two-phase cooling system includes an enclosure with a first volume, a second volume, and a heat source located in the first volume. The first volume is configured to contain a liquid coolant such that the liquid coolant is in contact with the heat source, and the second volume is configured to contain a vapor of the liquid coolant. The two-phase cooling system further includes a condenser located in the second volume that is configured to remove heat from the vapor so that the vapor condenses into a liquid. The two-phase cooling system further includes a deflector, which is configured to control a path of the vapor generated by the heat source, which flows through the liquid coolant toward a surface of the liquid coolant.

According to various embodiments, the deflector is configured to cause the vapor to flow away from the heat source. According to various embodiments, the heat source includes a vertical surface that generates the vapor and the deflector is configured to cause the vapor to flow away from the vertical surface as the vapor flows upwardly toward the surface of the liquid coolant. According to various embodiments, the heat source includes a first heat-generating component located in a lower portion of the heat source and a second heat-generating component located in an upper portion of the heat source. The deflector is located between the first heat-generating component and the second heat-generating component, and the deflector is configured to cause a first fraction of the vapor generated by the first heat-generating component to be deflected away from the second heat-generating component.

According to various embodiments, the deflector is configured to prevent the first fraction of the vapor from flowing in a volume occupied by a second fraction of the vapor generated by the second heat-generating component, and the deflector includes an upwardly angled surface that is neither parallel to nor perpendicular to the vertical surface of the heat source. According to various embodiments, the deflector is configured to cause the first fraction of the vapor generated by the first heat-generating component to flow along a direction parallel to the upwardly angled surface of the deflector. According to various embodiments, each of the first heat-generating component and the second heat-generating component have a first width in a horizontal direction and the deflector has a second width that is greater than the first width. According to various embodiments, a projected second area of the deflector overlaps a portion of a first area of the second heat-generating component in a side view along a direction perpendicular to the vertical surface of the heat source.

According to various embodiments, the two-phase cooling system includes a first impeller located below the deflector, such that the first impeller is configured to draw the liquid coolant and the first fraction of the vapor along the horizontal direction of the deflector toward a central portion of the deflector and to eject the liquid coolant and the first fraction of the vapor upwardly along a lower surface of the deflector. According to various embodiments, the first impeller is a double-suction impeller that draws the liquid coolant and the first fraction of the vapor from two horizontal directions.

According to various embodiments, the two-phase cooling system includes a second impeller located above the deflector, such that the second impeller is configured to draw the liquid coolant and the second fraction of the vapor along the horizontal direction of the second heat-generating component toward or away from a center of the second heat-generating component and to eject the liquid coolant and the second fraction of the vapor upwardly.

According to various embodiments, a method of cooling a heat source includes enclosing the heat source within a first volume of an enclosure that includes the first volume and a second volume, wherein the first volume includes a liquid coolant and such that the liquid coolant is in contact with the heat source. The method further includes heating the liquid coolant with heat from the heat source, thereby generating a vapor of the liquid coolant, and cooling the vapor with a condenser, which is located within the second volume, to thereby generate condensed liquid coolant that returns to the first volume. The method further includes controlling, with a deflector, a path of the vapor generated by the heat source that flows through the liquid coolant toward a surface of the liquid coolant.

According to various embodiments, the heat source includes a vertical surface that generates the vapor. In this regard, the heat source includes a first heat-generating component located in a lower portion of the heat source and a second heat-generating component located in an upper portion of the heat source. According to various embodiments, the deflector is located between the first heat-generating component and the second heat-generating component. In various embodiments, the method further includes causing the first fraction of the vapor generated by the first heat-generating component to be deflected away from the second heat-generating component by the deflector.

According to various embodiments, the method further includes activating a first impeller located below the deflector such that the first impeller draws the liquid coolant and the first fraction of the vapor along a horizontal direction of the deflector toward a central portion of the deflector and ejects the liquid coolant and the first fraction of the vapor upwardly along a lower surface of the deflector.

According to various embodiments, the method further includes activating a second impeller located above the deflector such that the second impeller performs operations including drawing the liquid coolant and a second fraction of the vapor, generated by the second heat-generating component, along the horizontal direction of the second heat-generating component toward or away from a center of the second heat-generating component and ejecting the liquid coolant and the second fraction of the vapor upwardly.

According to various embodiments, a method of cooling a computing device includes enclosing the computing device, which generates heat, within a first volume of an enclosure that includes the first volume and a second volume, wherein the first volume includes a liquid coolant and such that the liquid coolant is in contact with the computing device. The method further includes generating a vapor of the liquid coolant with the heat generated by the computing device and condensing the vapor into condensed liquid coolant with a condenser located within the second volume. The method further includes returning the condensed liquid coolant to the first volume and controlling, with a deflector, a path of the vapor generated by the computing device that flows through the liquid coolant toward a surface of the liquid coolant.

According to various embodiments, the computing device includes a first heat-generating component and a second heat-generating component located above the first heat-generating component. According to various embodiments, the deflector is located between the first heat-generating component and the second heat-generating component. According to various embodiments, the method further includes causing first fraction of the vapor generated by the first heat-generating component to be deflected away from the second heat-generating component by the deflector.

According to various embodiments, a projected second area of the deflector overlaps a portion of a first area of the second heat-generating component in a side view along a direction perpendicular to a vertical surface of the computing device. According to various embodiments, the method further includes activating a first impeller located below the deflector such that the first impeller draws the liquid coolant and the first fraction of the vapor along a horizontal direction of the deflector toward a central portion of the deflector and ejects the liquid coolant and the first fraction of the vapor upwardly along a lower surface of the deflector.

According to various embodiments, at least one of the first heat-generating component, or the second heat-generating component includes a plurality of circuit components arranged along a horizontal direction and separated from one another along the horizontal direction. In such embodiments, the method further includes activating at least one of a first impeller, located below the deflector, or a second impeller, located above the deflector, to draw the liquid coolant and the first fraction of the vapor generated by the first heat-generating component or second fraction of the vapor generated by the second heat-generating component, respectively, away from the first heat-generating component or the second heat-generating component.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure and that they may make various changes, substitutions, and alterations herein without departing from the spirit and scope of the present disclosure.

What is claimed is:

1. A two-phase cooling system, comprising:
an enclosure comprising a first volume and a second volume;
a heat source located in the first volume, wherein the first volume is configured to contain a liquid coolant such that the liquid coolant is in contact with the heat source, and the second volume is configured to contain a vapor of the liquid coolant;
a condenser located in the second volume that is configured to remove heat from the vapor so that the vapor condenses into a liquid; and
a deflector that is configured to control a path of the vapor, generated by the heat source, which flows through the liquid coolant toward a surface of the liquid coolant.

2. The two-phase cooling system of claim 1, wherein the deflector is configured to cause the vapor to flow away from the heat source.

3. The two-phase cooling system of claim 2, wherein:
the heat source comprises a vertical surface that generates the vapor; and
the deflector is configured to cause the vapor to flow away from the vertical surface as the vapor flows upward toward the surface of the liquid coolant.

4. The two-phase cooling system of claim 3, wherein:
the heat source comprises a first heat-generating component located in a lower portion of the heat source and a second heat-generating component located in an upper portion of the heat source;
the deflector is located between the first heat-generating component and the second heat-generating component; and
the deflector is configured to cause a first fraction of the vapor generated by the first heat-generating component to be deflected away from the second heat-generating component.

5. The two-phase cooling system of claim 4, wherein the deflector is configured to prevent the first fraction of the vapor from flowing in a volume occupied by a second fraction of the vapor generated by the second heat-generating component.

6. The two-phase cooling system of claim 4, wherein the deflector comprises an upwardly angled surface that is neither parallel to nor perpendicular to the vertical surface of the heat source.

7. The two-phase cooling system of claim 6, wherein the deflector is configured to cause the first fraction of the vapor generated by the first heat-generating component to flow along a direction parallel to the upwardly angled surface of the deflector.

8. The two-phase cooling system of claim 5, wherein:
each of the first heat-generating component and the second heat-generating component comprise a first width in a horizontal direction; and
the deflector comprises a second width that is greater than the first width.

9. The two-phase cooling system of claim 8, wherein, in a side view along a direction perpendicular to the vertical surface of the heat source, a projected second area of the deflector overlaps a portion of a first area of the second heat-generating component.

10. The two-phase cooling system of claim 9, further comprising:
a first impeller located below the deflector,
wherein the first impeller is configured to draw the liquid coolant and the first fraction of the vapor along the horizontal direction of the deflector toward a central portion of the deflector and to eject the liquid coolant and the first fraction of the vapor upwardly along a lower surface of the deflector.

11. The two-phase cooling system of claim 10, wherein the first impeller is a double-suction impeller that draws the liquid coolant the first fraction of the vapor from two horizontal directions.

12. The two-phase cooling system of claim 9, further comprising:
a second impeller located above the deflector,
wherein the second impeller is configured to draw the liquid coolant and the second fraction of the vapor along the horizontal direction of the second heat-generating component toward or away from a center of the second heat-generating component and to eject the liquid coolant and the second fraction of the vapor upwardly.

13. A method of cooling a heat source, comprising:
enclosing the heat source within a first volume of an enclosure that comprises the first volume and a second volume, wherein the first volume includes a liquid coolant, such that the liquid coolant is in contact with the heat source;
heating the liquid coolant with heat from the heat source, thereby generating a vapor of the liquid coolant;
cooling the vapor with a condenser, which is located within the second volume, to thereby generate condensed liquid coolant that returns to the first volume; and
controlling, with a deflector, a path of the vapor generated by the heat source that flows through the liquid coolant toward a surface of the liquid coolant.

14. The method of claim 13, wherein:
the heat source comprises a vertical surface that generates the vapor;
the heat source comprises a first heat-generating component located in a lower portion of the heat source and a second heat-generating component located in an upper portion of the heat source;
the deflector is located between the first heat-generating component and the second heat-generating component; and
the method further comprising:
causing a first fraction of the vapor generated by the first heat-generating component to be deflected away from the second heat-generating component by the deflector.

15. The method of claim 14, further comprising:
activating a first impeller located below the deflector such that the first impeller draws the liquid coolant and the first fraction of the vapor along a horizontal direction of the deflector toward a central portion of the deflector and ejects the liquid coolant and the first fraction of the vapor upwardly along a lower surface of the deflector.

16. The method of claim 15, further comprising:
activating a second impeller located above the deflector such that the second impeller performs operations comprising:
drawing the liquid coolant and a second fraction of the vapor, generated by the second heat-generating component, along the horizontal direction of the second heat-generating component toward or away from a center of the second heat-generating component; and
ejecting the liquid coolant and the second fraction of the vapor upwardly.

17. A method of cooling a computing device, comprising:
enclosing the computing device, which generates heat, within a first volume of an enclosure that comprises the first volume and a second volume, wherein the first volume includes a liquid coolant, such that the liquid coolant is in contact with the computing device;
generating a vapor of the liquid coolant with the heat generated by the computing device;
condensing the vapor into condensed liquid coolant with a condenser located within the second volume;
returning the condensed liquid coolant to the first volume; and
controlling, with a deflector, a path of the vapor, generated by the computing device, which flows through the liquid coolant toward a surface of the liquid coolant.

18. The method of claim 17, wherein:
the computing device comprises a first heat-generating component and a second heat-generating component, which is located above the first heat-generating component;
the deflector is located between the first heat-generating component and the second heat-generating component; and
the method further comprising:
causing a first fraction of the vapor generated by the first heat-generating component to be deflected away from the second heat-generating component by the deflector.

19. The method of claim 18, wherein, in a side view along a direction perpendicular to a vertical surface of the computing device, a projected second area of the deflector overlaps a portion of a first area of the second heat-generating component;
the method further comprising:
activating a first impeller located below the deflector such that the first impeller draws the liquid coolant and the first fraction of the vapor along a horizontal direction of the deflector toward a central portion of the deflector and ejects the liquid coolant and the first fraction of the vapor upwardly along a lower surface of the deflector.

20. The method of claim 18, wherein at least one of the first heat-generating component or the second heat-generating component comprises a plurality of circuit components arranged along a horizontal direction and separated from one another along the horizontal direction;
the method further comprising:
activating at least one of a first impeller located below the deflector or a second impeller located above the deflector to draw the liquid coolant and the first fraction of the vapor generated by the first heat-generating component or a second fraction of the vapor generated by the second heat-generating component respectively away from the first heat-generating component or the second heat-generating component.
